(19) United States
(12) Patent Application Publication
(10) Pub. No.: US 2026/0134923 A1
(43) Pub. Date: May 14, 2026

(54) MEMORY PROGRAM CONTROL CIRCUIT

(71) Applicant: EMEMORY TECHNOLOGY INC., HSINCHU (TW)

(72) Inventors: CHIA-FU CHANG, HSINCHU COUNTY (TW); JEN-YU PENG, HSINCHU COUNTY (TW)

(21) Appl. No.: 19/385,946

(22) Filed: Nov. 11, 2025

Related U.S. Application Data
(60) Provisional application No. 63/719,167, filed on Nov. 12, 2024.

(51) Int. Cl. G11C 16/10; G11C 16/08; G11C 16/32

(52) U.S. Cl. CPC G11C 16/102; G11C 16/08; G11C 16/32

(57) ABSTRACT

A memory program control circuit includes a main counter, N registers, N DFFs, an update control unit, a group counter, and a write control unit. The main counter increments a main counter value according to a clock signal. The N registers store N bits to be written into a memory. The update control unit updates the N DFFs with the data stored in the N registers sequentially as the main counter value increments, and a write buffer is updated by a bit stored in a corresponding DFF as the DFF is updated. The group counter increments a group counter value each time a DFF is updated with a bit of a first type, and generates a group write enable signal when the group counter value reaches M, thereby having the write control unit perform a group write operation upon the memory.

### CROSS REFERENCE

This application claims the benefit of prior-filed U.S. provisional application No. 63/719,167, filed on November 12, 2024, which is incorporated by reference in its entirety.

### TECHNICAL FIELD

The present disclosure relates to a memory program control circuit, and more particularly, to a memory program control circuit capable of reducing the write time of a memory.

### DISCUSSION OF THE BACKGROUND

Non-volatile memory (NVM) is a type of memory capable of retaining stored information even when the power supply is turned off. This characteristic makes NVM essential for a wide range of applications where data persistence is critical. Common examples of non-volatile memory include flash memory, electrically erasable programmable read-only memory (EEPROM), and magnetoresistive random access memory (MRAM). These memories can be used to store firmware, user data, and system configurations reliably without the need for continuous power.

However, during the programming operation of non-volatile memory, a high voltage is typically required to change the storage states of the memory cells. For example, the program operation may involve injecting electrons into a floating gate or rupturing the gate structure with a high voltage, which can generate significant currents. Due to the demands for high voltages and high currents, there is usually a limitation on the number of bits that can be programmed simultaneously. This constraint results in longer programming times, as bits must be programmed in smaller groups. Therefore, how to reduce the programming time of non-volatile memory has become a critical issue to be solved in the field.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a memory program control circuit. The memory program control circuit includes a main counter, N registers, N D flip-flops (DFFs), an update control unit, a group counter, and a main control unit. The main counter increments a main counter value according to a clock signal. The N registers store N bits of a word to be written into a memory, wherein N is an integer greater than 1. The N DFFs are coupled to N write buffers of the memory. The update control unit is coupled to the N registers. The update control unit updates the N DFFs with the N bits stored in the N registers one at a time as the main counter value increments. A write buffer of the N write buffers is updated by a bit stored in a corresponding DFF of the N DFFs as the corresponding DFF is updated. The group counter is coupled to the update control unit. The group counter increments a group counter value each time a DFF of the N DFFs is updated with a bit of a first type, and when the group counter value reaches M, generates a first group write enable signal so as to request a write control unit of the memory to perform a first group write operation to write a plurality of bits stored in a plurality of write buffers of the N write buffers into the memory, wherein M is smaller than N. The main control unit generates the clock signal to the main counter.

Another aspect of the present disclosure provides a method for writing data into a memory. The method includes storing N bits of a word to be written into the memory in N registers, incrementing a main counter value according to a clock signal, updating N DFFs with the N bits stored in the N registers one at a time as the main counter value increments, updating a write buffer of N write buffers by a bit stored in a corresponding DFF of the N DFFs as the corresponding DFF is updated, incrementing a group counter value each time a DFF of the N DFFs is updated with a bit of a first type; and when the group counter value reaches M, generating a first group write enable signal to perform a first group write operation upon the memory so as to write a plurality of bits stored in a plurality of write buffers of the N write buffers into the memory, wherein N is an integer greater than 1, and M is smaller than N.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a non-volatile memory cell according to one embodiment of the present disclosure.

FIG. 2 shows the bias voltages provided to the memory cell in FIG. 1 when a program operation is performed.

FIG. 3 shows the bias voltages provided to the memory cell in FIG. 1 when a read operation is performed.

FIG. 4 shows a memory according to one embodiment of the present disclosure.

FIG. 5 shows a memory program control circuit according to one embodiment of the present disclosure.

FIG. 6 shows a flow chart of a method for writing data into a memory according to one embodiment of the present embodiment.

FIG. 7 shows a timing diagram of the signals generated or received by the memory program control circuit in FIG. 5 according to one embodiment of the present disclosure.

### DETAILED DESCRIPTION

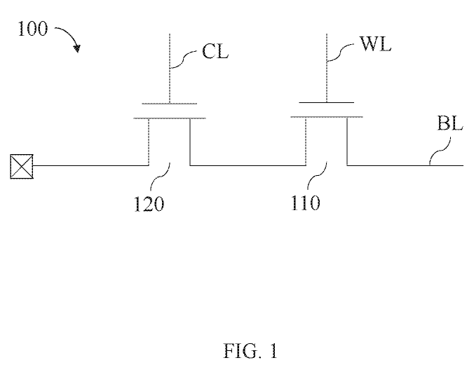

FIG. 1 shows a non-volatile memory cell 100 according to one embodiment of the present disclosure. The non-volatile memory cell 100 includes a selection transistor 110 and an anti-fuse transistor 120. The selection transistor 110 has a first terminal coupled to a bit line BL, a second terminal, and a control terminal coupled to a word line WL. The anti-fuse transistor 120 has a first terminal coupled to the second terminal of the selection transistor 110, a second terminal being floating, and a control terminal coupled to a control line CL.

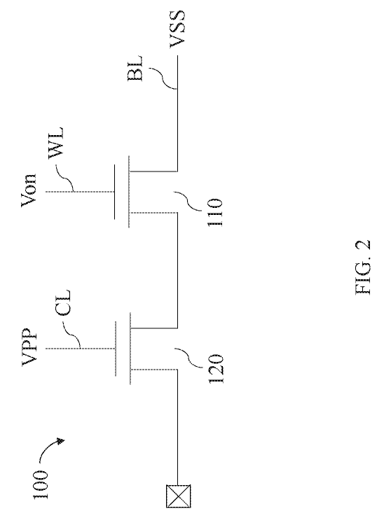

FIG. 2 shows the bias voltages provided to the memory cell 100 when a program operation is performed. As shown in FIG. 2, during the program operation, the control line CL may receive a program voltage VPP, the bit line BL may receive a system voltage VSS, such as a ground voltage, and the word line WL may receive an on voltage Von. In some embodiments, the on voltage Von can be a power voltage, for example but not limited to, the on voltage Von can be 1.2V. Also, the program voltage VPP can be a voltage higher than the power voltage, and can be, for example but not limited to, 5V.

In such case, during the program operation, the selection transistor 110 is turned on, and the voltage stress withstood by the gate of the anti-fuse transistor 120 is equal to the program voltage VPP. Such high voltage stress can rupture the gate oxide of the anti-fuse transistor 120, and thus, a low resistance path between the control terminal and the first terminal of the anti-fuse transistor 120 can be created. In some embodiments, after the memory cell 100 is programmed, the memory cell

100 can be deemed as storing a bit of a first type (e.g., logic 1), and before the memory cell 100 is programmed, the memory cell 100 can be deemed as storing a bit of a second type (e.g., logic 0).

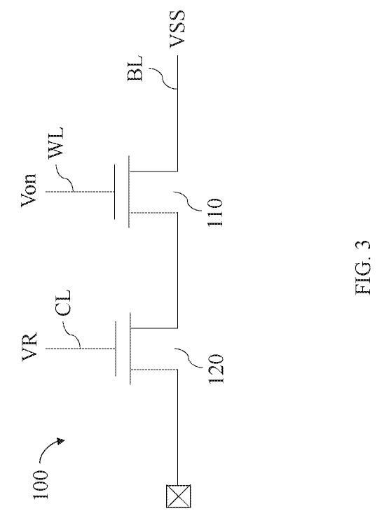

FIG. 3 shows the bias voltages provided to the memory cell 100 when a read operation is performed. As shown in FIG. 3, during the read operation, the control line CL may receive a read voltage VR, which may be close to the power voltage, the bit line BL may receive the system voltage VSS, and the word line WL may receive the on voltage Von. In such case, if the memory cell 100 has been programmed, then a significant current can flow from the control line CL through the gate structure of the anti-fuse transistor 120 that has been ruptured, and the selection transistor 110 can also be turned on so the significant read current can be sensed on the bit line BL. However, if the memory cell 100 has not been programmed, then only an insignificant current or zero current can be sensed on the bit line BL. Consequently, the types of the bit data stored in the memory cell 100 can be read by sensing the current on the bit line BL. Specifically, if a significant current is sensed, then the memory cell 100 can be identified as storing a bit of the first type (e.g., logic 1), and if no significant current is sensed, then the memory cell 100 can be identified as storing a bit of the second type (e.g., logic 0).

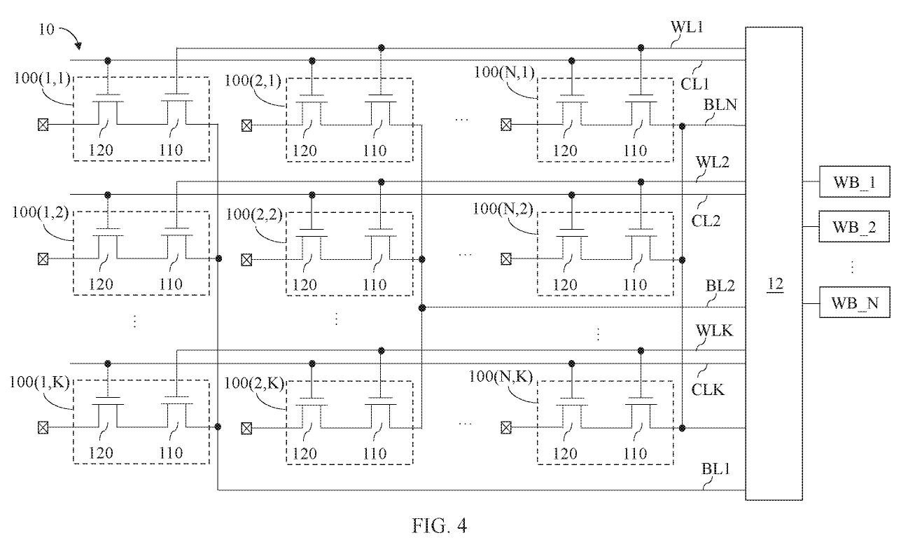

FIG. 4 shows a memory 10 according to one embodiment of the present disclosure. The memory 10 includes a memory array formed by memory cells 100(1,1) to 100(N,K), wherein N and K are integers greater than 1, and each of the memory cells 100(1,1) to 100(N,K) may have the same structure as the memory cell 100 shown in FIG. 1. In addition, the memory cells 100(1,1) to 100(N,K) are arranged as a plurality of words. For example, the memory cells 100(1,1) to 100(N,1) are coupled to a same word line WL1 and a same control line CL1, and thus, can be deemed as a word. Similarly, memory cells 100(1,2) to 100(N,2) are coupled to a same word line WL2 and a same control line CL2, and memory cells 100(1,K) to 100(N,K) are coupled to a same word line WLK and a same control line CLK.

Furthermore, memory cells in the same word may be coupled to different bit lines so that the memory cells in the same word can still be operated individually. For example, the memory cell 100(1,1) is coupled to a bit line BL1, the memory cell 100(2,1) is coupled to a bit line BL2, and the memory cell 100(N,1) is coupled to a bit line BLN. In such case, memory cells in a same word may be selected through the same word line for performing operations at the same time. In other words, ideally, it is possible to write N bits of data to the memory cells 100(1,1) to 100(N,1) simultaneously.

In the present embodiment, the memory 10 may further include a write control unit 12 and N write buffers WB_1 to WB_N. It should be noted that the write control unit 12 is an example of a peripheral circuit for performing the write operations upon the memory array and should not be construed as restrictive or limiting the invention to the particular forms disclosed. In some embodiments, the memory 10 may further include some other peripheral circuits (not shown) for performing the read operations or other required operations. Also, alternative arrangements, components, and implementations that achieve the same or similar functionality are fully contemplated within the scope of the disclosure.

The write control unit 12 may provide the necessary voltages to the word lines WL1 to WLK, the control lines CL1 to CLK, and the bit lines BL1 to BLN according to the bits stored in the write buffers WB_1 to WB_N to be written. For example, if the bit stored in the write buffer WB_1 is logic 0, the bits stored in the write buffers WB_2 to WB_N are logic 1, and the bits of the write buffers WB_1 to WB_N are to be written into the memory cells 100(1,1) to 100(N,1), then, the write control unit 12 may provide the on voltage Von to the word line WL1 for selecting the memory cells 100(1,1) to 100(N,1). Also, the write control unit 12 may provide the program voltage VPP to the control line CL1, provide the on voltage Von to the bit line BL1, and provide the system voltage VSS to the bit lines BL2 to BLN. In such case, the memory cells 100(2,1) to 100(N,1) can be

programmed as the case shown in FIG. 2, while the memory cell 100(1,1) can be inhibited from being programmed (since the voltage stress applied to the anti-fuse transistor 120 is reduced to the program voltage VPP minus the on voltage Von) during the program operation of the memory cells 100(2,1) to 100(N,1).

However, since the program operation may involve high voltages and high currents (e.g., a high current may be induced when the gate structure of the anti-fuse transistor is ruptured during the program operation), there may be a limitation on the number of memory cells that can be programmed simultaneously so as to protect the components of the memory 10 from being damaged by the high currents. Therefore, bits of a word are usually written into the memory cells in several separate operations. For example, if N equals to 32, and the memory 10 only allows 8 memory cells to be programmed at the same time, then, to write 32 bits to memory cells in the same word, it will take four separate write operations, thereby ensuring that the number of memory cells to be programmed each time does not excess the limited number (e.g., 8). Similar limitations also apply to the other types of non-volatile memory cell, such as a floating gate memory cells or a charge trap memory cell.

In such case, the write operation is not performed in the most efficient way. Specifically, if the bits in a word are normally distributed, then generally there may be about16 bits of logic 1 and about 16 bits of logic 0 in the 32 bits. That is, there may be only 16 memory cells of the 32 memory bits that need to be programmed, and ideally, the 16 memory cells can be programmed in two write operations without exceeding the limitation of the memory 10. However, without knowing the content of the bits to be written to the memory cells, the previous scheme may always require four separate write operations. Accordingly, the present disclosure provides a memory program control circuit and a method for writing data into the memory that can enhance the efficiency of the write operations and reduce the overall write time of the memory.

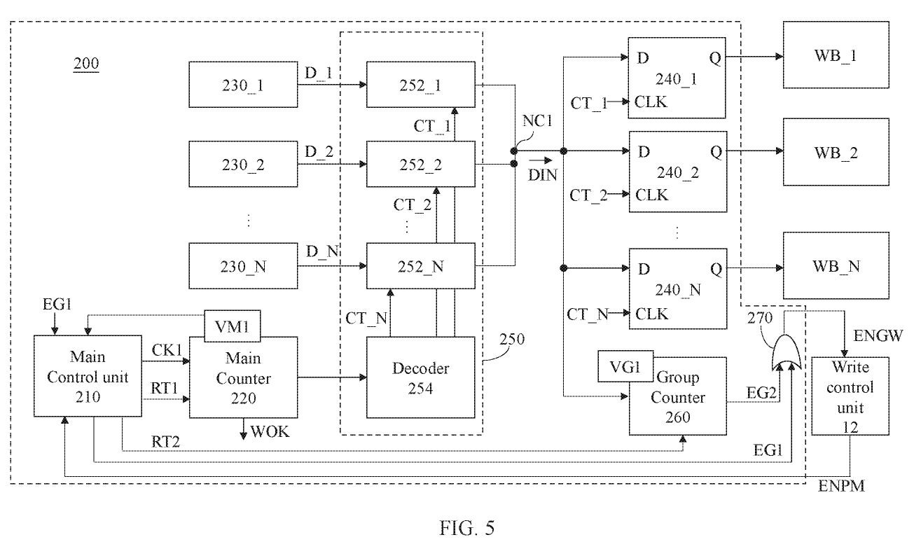

FIG. 5 shows a memory program control circuit 200 according to one embodiment of the present disclosure. The memory program control circuit 200 includes a main control unit 210, a main counter 220, N registers 230_1 to 230_N, N D flip-flops (DFFs) 240_1 to 240_N, an update control unit 250, and a group counter 260. In some embodiments, the memory program control circuit 200 can be used to write data into the memory 10. However, the present disclosure is not limited thereto. In some embodiments, the memory program control circuit 200 can be used to write data into other types of memories that have limitations on the number of memory cells that can be programmed simultaneously.

In the present embodiment, the memory program control circuit 200 can store the bits of the word to be written into the memory 10 to the registers 230_1 to 230_N, and update the DFFs 240_1 to 240_N with the bits D_1 to D_N stored in the registers 230_1 to 230_N one by one. The memory program control circuit 200 may utilize the main counter 220 to count the total number of DFFs that have been updated, so that the main control unit 210 can be aware of the current writing progress of the word. In addition, the memory program control circuit 200 can further use the group counter 260 to count the number of DFFs that have been updated with bits of the first type so as to indicate the number of memory cells that need to be programmed currently. Based on such information, the memory program control circuit 200 can determine to perform a group write operation when the number of the memory cells need to be programmed has reached the maximum allowable number of the memory 10. With the main counter 220 and the group counter 260, the memory program control circuit 200 is able to request the group write operation only in the necessary situation, and thus, the efficiency of the write operations can be improved and the overall write time of the memory 10 can be reduced.

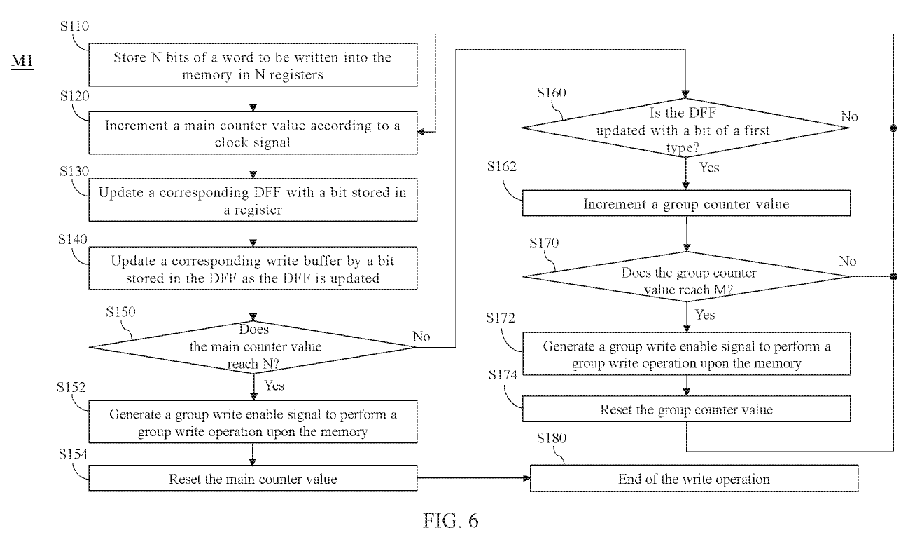

FIG. 6 shows a flow chart of a method M1 for writing data into a memory according to one embodiment of the present embodiment. In some embodiments, the method M1 can be performed with the memory program control circuit 200.

For example, in the present embodiment, each word may include N bits, and in step S110, the registers 230_1 to 230_N can store the N bits of data in the word to be written into the selected memory cells (e.g., the memory cells 100(1,1) to 100(N,1)) of the memory 10.

In step S120, the main control unit 210 may generate a clock signal CK1, and the main counter 220 may increment a main counter value VM1 according to the clock signal CK1. In some embodiments, the main counter value VM1 can have an initial value of 0, and can be incremented (e.g., incremented by 1) whenever a rising edge of the clock signal CK1 is detected. However, the present disclosure is not limited thereto. In some embodiments, the initial value of the main counter value VM1 can be set to other number according to the system need. Also, in some other embodiments, the main counter value VM1 can be incremented whenever a falling edge of the clock signal CK1 is detected or whenever a rising edge or a falling edge is detected.

In step S130, the update control unit 250 can update the DFFs 240_1 to 240_N with the N bits D_1 to D_N stored in the registers 230_1 to 230_N one at a time as the main counter value VM1 increments. For example, as shown in FIG. 5, the update control unit 250 can be coupled to the N registers 230_1 to 230_N, and the update control unit 250 may include N switches 252_1 to 252_N and a decoder 254. Each of the switches 252_1 to 252_N has an input terminal coupled to one of the registers 230_1 to 230_N and an output terminal coupled to a common node NC1, which is coupled to data input terminals of the DFFs 240_1 to 240_N.

The decoder 254 can generate N control signals CT_1 to CT_N to control the switches 252_1 to 252_N according to the main counter value VM1. Furthermore, each of the DFFs 240_1 to 240_N may also receive a corresponding control signal of the control signals CT_1 to CT_N through its clock terminal so that the DFFs 240_1 to 240_N can be updated by the bits D_1 to D_N stored in the registers 230_1 to 230_N one at a time as the main counter value VM1 increments.

For example, if the main counter value VM1 is set to 0 initially, then

when the main counter value VM1 is incremented to 1, the decoder 254 can generate the control signal CT_1 for turning on the switch 252_1 (all the other switches are turned off) and triggering the DFF 240_1, so the bit D_1 stored in the register 230_1 can be transmitted to the common node NC1 as the input data DIN for updating the DFF 240_1. Subsequently, when the main counter value VM1 is incremented to 2, the decoder 254 can generate the control signal CT_2 for turning on the switch 252_2 (all the other switches are turned off) and triggering the DFF 240_2, so the bit D_2 stored in the register 230_2 can be transmitted to the common node NC1 as the input data DIN for updating the DFF 240_2, and so on. However, the present disclosure is not limited by the structure of the update control unit 250 shown in FIG. 5. In some embodiments, the update control unit 250 may be implemented by a different structure and may include some different components, such as multiplexer and/or demultiplexer.

Furthermore, in step S140, a corresponding write buffer can be updated by a bit of data stored in the DFF as the DFF is updated. For example, when the DFF 240_1 is updated, the write buffer WB_1 in the memory 10 can be updated by the bit stored and outputted by the DFF 240_1, and when the DFF 240_2 is updated, the write buffer WB_2 in the memory 10 can be updated by the bit stored and outputted by the DFF 240_2, and so on.

In step S150, the main control unit 210 may receive the main counter value VM1 from the main counter 220 and check if the main counter value VM1 has reached N. If the main counter value VM1 has reached N, it may indicate that all the write buffers WB_1 to WB_N of the word to be written have been updated, and the main control unit 210 may generate a group write enable signal EG1 to the write control unit 12 of the memory 10, thereby requesting the write control unit 12 to perform a group write operation upon the selected memory cells in the memory 10.

Also, in step S154, the main control unit 210 can reset the main counter 220 (e.g., setting the main counter value VM1 to 0) by, for example, sending the reset signal RT1, and the write operation can be ended in step S180. In

some embodiments, the main control unit 210 or the main counter 220 may further output a write operation complete signal WOK to the external data source so that the data source can further transmit the bits of the next word to be written into memory 10 to the memory program control circuit 200, and the memory program control circuit 200 may perform the next write operation by starting from step S110 again.

However, in step S150, if the main counter value VM1 has not reached N, it means that there is still write buffer that needs to be updated. In such case, the group counter 260 may further check if the number of memory cells waiting to be programmed has reached the limitation of the memory 10. For example, the group counter 260 can be coupled to the common node NC1, and each time when one of the DFFs 240_1 to 240_N is updated, the group counter 260 may perform the step S160 to check if the DFF is updated with a bit of the first type (e.g., logic 1). If the DFF is updated with a bit of the first type, it indicates that a corresponding memory cell will need to be programmed, and thus, the group counter 260 can increment the group counter value VG1 in step S162.

Subsequently, the group counter 260 may further check if the group counter value VG1 has reached a predetermined number M in step S170, where M is a positive integer smaller than N and corresponds to the maximum number of memory cells that the memory 10 allows to program at a same time (i.e., the limitation on the number of bits that can be programmed simultaneously). In this case, M can be 8. That is, the memory 10 only allows to program 8 memory cells at the same time at most. If the group counter value VG1 reaches M, it may indicate that there are M memory cells need to be programmed, and thus, the group counter 260 can generate a group write enable signal EG2 to the write control unit 12 in step S172 so that the write control unit 12 can perform a group write operation upon the memory 10 and write the bits stored in the write buffers that have been updated by the previous steps into the memory 10. Subsequently, the group counter 260 can reset the group counter value VG1 in step S174 according to, for example, the reset signal RT2 sent by the main control unit 210, and step S120 will be performed again. In the present embodiment, the group

write enable signal EG1 generated by the main control unit 210 and the group write enable signal EG2 generated by the group counter 260 can be ORed by an OR gate 270, so that the write control unit 12 may receive the group write enable signal ENGW through one input terminal whenever the group write enable signal EG1 or the group write enable signal EG2 is generated. However, the present disclosure is not limited thereto.

Furthermore, if the group counter value VG1 has not reached M, it may indicate that the number of memory cells need to be programmed has not reach the limitation of the memory 10, and thus, the group write operation can be performed latter. Therefore, step S120 can be performed again so as to keep updating the rest of DFFs and write buffers. As a result, the number of group write operations will not be increased unnecessarily, thereby ensuring the overall writing efficiency of the memory 10.

Furthermore, if the DFF is not updated with a bit of the first type but a bit of the second type, it means that the corresponding memory cell will not be programmed (i.e., will be inhibited from being programmed in the following write operation), and thus, the group counter 260 will not increment the group counter value VG1. That is, in such case, step S162 will not be performed to increment the group counter value VG1, and step S120 will be performed again after step S160.

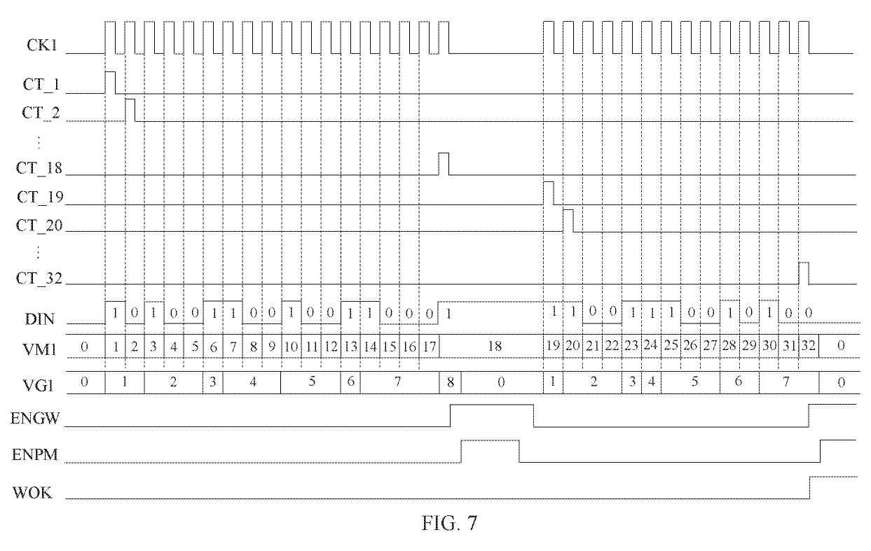

FIG. 7 shows a timing diagram of the signals generated or received by the memory program control circuit 200 according to one embodiment of the present disclosure. As shown in FIG. 7, as the main control unit 210 starts to generate the clock signal CK1, the main counter 220 starts to increment the main counter value VM1 from 0, and the decoder 254 starts to generate the control signals CT_1, CT_2, and so on. Correspondingly, the DFF can be updated by the corresponding registers through the update control unit 250, and the group counter value VG1 is also incremented when the DFF is updated with a bit of the first type.

Specifically, in the current example, the word to be written into of the memory 10 includes 32 bits of the data as

"101001100100110001-11001110010100". As shown in FIG. 7, as the clock signal CK1 toggles, the data stored in the registers 230_1 to 230_18 will be updated to the DFFs 240_1 to 240_18 in each cycle of the clock signal CK1, and the main counter value VM1 will be incremented to 18. Meanwhile, the group counter value VG1 can be incremented when the DFF 240_1, DFF240_3, DFF 240_6, DFF 240_7, DFF 240_10, DFF 240_13, and DFF 240_14 is updated by the bit of the first type (e.g., logic 1), and will be incremented to be M (in this case M=8) when the 18^{th} DFF240_18 is updated. In such case, when the group counter 260 performs step S170 to check if the group counter value VG1 has reached the limitation or not, it will determines that the condition of step S170 is met, and will perform step S172 subsequently to generate the group write enable signal EG2 to the write control unit 12, thereby having the write control unit 12 to write the first 18 bits of the word into the memory 10 by a group write operation. In this example, since the first 18 bits of the word only include 8 bits of 1, there are only 8 memory cells of the memory 10 need to be programmed while the other 10 memory cells of the memory can be inhibited from being programmed. As a result, the number of memory cells to be programmed will not exceed the limitation of the memory 10.

In some embodiments, the write buffers WB_1 to WB_N may all store a bit of the second type (e.g., logic 0) by default before updated, and the group write operation may be performed to write all the bits in the write buffers WB_1 to WB_N to the corresponding memory cells. In such case, since the last 14 bits of the write buffers WB_19 to WB_32 are not updated yet, the bits of the write buffers WB_19 to WB_32 will all be the second type and will not affect the group write operation. Furthermore, in some embodiments, after the group write operation is performed, the write control unit 12 or the main control unit 210 may further reset the write buffers WB_1 to WB_18 that have been updated (or all the write buffers WB_1 to WB_32) after the group write operation is finished so that the write buffers that have been updated and used for the group write operation will not affect the subsequent group write operations.

In the present embodiment, the main control unit 210 may stop toggling the clock signal CK1 during the group write operation of the memory 10 so as to stop the main counter 220 from keeping incrementing the main counter value VM1. Also, the group counter value VG1 can be reset after the group write enable signal EG2 is generated. Subsequently, the main control unit 210 may restart to toggle the clock signal CK1 when a notification signal ENPM received from the write control unit 12 is released (e.g., back to logic 0) after the group write operation is finished so that the main counter 220 can continue to increment the main counter value VM1 from its previous value 18.

In such case, the group counter value VG1 will be incremented when the DFF 240_19, DFF240_20, DFF240_23, DFF 240_24, DFF240_25, DFF240_28, and DFF 240_30 is updated by the bit of the first type (e.g., logic 1), however, before the group counter value VG1 reaches M (in this case M=8), the main counter value VM1 will be incremented to be N (in this case N=32) first, and thus, when the main control unit 210 performs step S150 to check if the main counter value VM1 has reached N or not, it will determines that the condition of step S150 is met, and will perform step S152 subsequently to generate the group write enable signal EG1 to the write control unit 12, thereby having the write control unit 12 write the remaining 14 bits of the word into the memory 10 by a group write operation. As a result, with the memory program control circuit 200 and the method M1, the write control unit 12 only needs to perform two times of group write operations to write all the 32 bits of data into the memory 10 without exceeding the limitation of the memory 10. Therefore, the efficiency of the write operations can be improved and the overall write time of the memory 10 can be reduced.

The present disclosure is not limited by the performing order shown in FIG. 7. In some embodiments, the performing order of the method M1 may be rearranged according to the system need. For example, in some embodiments, the conditions listed in steps S160 and S170 may be checked before the condition listed in step S150, however, some more adjustment may be required to ensure the correctness. Furthermore, in some

embodiments, the conditions in steps S150, S160, and S170 may also be adjusted according to the system needs. For example, according to the timings and the schemes that the main counter value and the group counter value are incremented, the targeted value N set in step S150 may be changed to (N-1), and the targeted value M set in step S170 may be changed to (M-1); however, the concept of counting the number of DFFs that have been updated by the main counter value VM1 and the number of DFFs that have been updated with bits of the first type by the group counter value VG1 should still apply.

In summary, the memory program control circuits and the methods for writing data into a memory provided by the embodiments of the present disclosure can utilize the main counter to count the total number of DFFs that have been updated and utilize the group counter to count the number of DFFs that have been updated with bits of the first type so as to indicate the number of memory cells that need to be programmed currently. Based on such information, the memory program control circuit and the method provided by the present disclosure is able to determine to perform a group write operation when the number of the memory cells need to be programmed has reached the maximum allowable number of the memory. As a result, the group write operations can be performed when necessary, and thus, the efficiency of the write operations can be improved and the overall write time of the memory can be reduced.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A memory program control circuit comprising:
a main counter configured to increment a main counter value according to a clock signal;
N registers configured to store N bits of a word to be written into a memory, wherein N is an integer greater than 1;
N D flip-flops (DFFs) coupled to N write buffers of the memory;
an update control unit coupled to the N registers and configured to update the N DFFs with the N bits stored in the N registers one at a time as the main counter value increments, wherein a write buffer of the N write buffers is updated by a bit stored in a corresponding DFF of the N DFFs as the corresponding DFF is updated;
a group counter coupled to the update control unit and configured to increment a group counter value each time a DFF of the N DFFs is updated with a bit of a first type, and when the group counter value reaches M, generate a first group write enable signal so as to request a write control unit of the memory to perform a first group write operation to write a plurality of bits stored in a plurality of write buffers of the N write buffers into the memory, wherein M is smaller than N; and
a main control unit configured to generate the clock signal to the main counter.

2. The memory program control circuit of claim 1, wherein the main control unit is further configured to reset the group counter value after the first group write enable signal is generated.

3. The memory program control circuit of claim 1, wherein the main control unit is further configured to, when the main counter value reaches N, generate a second group write enable signal to the write control unit, thereby having the write control unit perform a second group write operation to write at least one data stored in at least one write buffer of the N write buffers into the memory.

4. The memory program control circuit of claim 3, wherein the main control unit is further configured to reset the main counter value and the group counter value after the second group write enable signal is generated.

5. The memory program control circuit of claim 1, wherein the write control unit or the main control unit is further configured to reset the plurality of write buffers of the N write buffers after the first group write operation is finished.

6. The memory program control circuit of claim 1, wherein the main control unit stops toggling the clock signal during the first group write operation so as to stop the main counter from incrementing, and restart to toggle the clock signal after the first group write operation is finished so as to have the main counter continue to increment.

7. The memory program control circuit of claim 1, wherein M corresponds to a maximum number of memory cells that the memory allows to program at a same time.

8. The memory program control circuit of claim 1, wherein the memory is a non-volatile memory.

9. The memory program control circuit of claim 1, wherein the update control unit comprises:
N switches, each having an input terminal coupled to a register of the N registers, and an output terminal coupled to a common node, wherein data input terminals of the N DFFs are coupled to the common node; and
a decoder configured to generate N control signals to control the N switches according to the main counter value so as to allow the N DFFs to be updated by the N bits stored in the N registers one at a time as the main counter value increments.

10. The memory program control circuit of claim 9, wherein each of the N DFFs has a clock terminal configured to receive a control signal of the N control signals.

11. The memory program control circuit of claim 1, wherein a memory cell of the memory stores a bit of a second type different from the first type before the memory cell is programmed.

12. A method for writing data into a memory comprising:
storing N bits of a word to be written into the memory in N registers, wherein N is an integer greater than 1;
incrementing a main counter value according to a clock signal;
updating N D flip-flops (DFFs) with the N bits stored in the N registers one at a time as the main counter value increments;
updating a write buffer of N write buffers by a bit stored in a corresponding DFF of the N DFFs as the corresponding DFF is updated;
incrementing a group counter value each time a DFF of the N DFFs is updated with a bit of a first type; and
when the group counter value reaches M, generating a first group write enable signal to perform a first group write operation upon the memory so as to write a plurality of bits stored in a plurality of write buffers of the N write buffers into the memory, wherein M is smaller than N.

13. The method of claim 12, further comprising:
resetting the group counter value after the first group write enable signal is generated.

14. The method of claim 12, further comprising:
when the main counter value reaches N, generating a second group write enable signal to perform a second group write operation upon the memory so as to write at least one data stored in at least one write buffer of the N write buffers into the memory.

15. The method of claim 14, further comprising:
resetting the main counter value and the group counter value after the second group write enable signal is generated.

16. The method of claim 12, further comprising:
resetting the plurality of write buffers of the N write buffers after the first group write operation is finished.

17. The method of claim 12, wherein during the first group write operation, the clock signal stops toggling.

18. The method of claim 12, wherein M corresponds to a maximum number of memory cells that the memory allows to program at a same time.

19. The method of claim 12, wherein the memory is a non-volatile memory.

20. The method of claim 12, wherein a memory cell of the memory stores a bit of a second type different from the first type before the memory cell is programmed.
